(19) United States
(12) Patent Application Publication
(10) Pub. No.: US 2023/0216402 A1
(43) Pub. Date: Jul. 6, 2023

(54) Gate Drive Voltage Regulation Apparatus and Control Method

(71) Applicant: NuVolta Technologies (Hefei) Co., Ltd., Hefei (CN)

(72) Inventors: Olivier Metayer, Beaverton, OR (US); Lingting Ye, Lincoln, RI (US); Paolo Baruzzi, Fremont, CA (US)

(21) Appl. No.: 17/646,918

(22) Filed: Jan. 4, 2022

(51) Int. Cl. H02M 3/156; H02M 1/00

(52) U.S. Cl. CPC H02M 3/156; H02M 1/0006

(57) ABSTRACT

A method includes in a first operating mode of a load switch comprising two back-to-back connected transistors, reducing at least one of a first gate-to-source voltage and a second gate-to-source voltage of the two back-to-back connected transistors from a normal gate drive voltage potential to a reduced gate drive voltage potential, and in a second operating mode of the load switch, increasing the at least one of the first gate-to-source voltage and the second gate-to-source voltage of the two back-to-back connected transistors from the reduced gate drive voltage potential to the normal gate drive voltage potential.

### TECHNICAL FIELD

The present invention relates to a gate drive voltage regulation apparatus and control method, and, in particular embodiments, to a gate drive voltage regulation apparatus for reducing power consumption in a battery powered electronic device.

### BACKGROUND

As semiconductor technologies evolve, metal oxide semiconductor field effect transistors (MOSFET) have been widely used in integrated circuits. MOSFETs are voltage controlled devices. When a control voltage is applied to the gate of a MOSFET and the control voltage is greater than the threshold of the MOSFET, a conductive channel is established between the drain and the source of the MOSFET. After the conductive channel has been established, a current flows between the drain and the source of the MOSFET. On the other hand, when the control voltage applied to the gate is less than the threshold of the MOSFET, the MOSFET is turned off accordingly.

MOSFETs may include two major categories, namely n-channel MOSFETs and p-channel MOSFETs. According to the structure difference, MOSFETs can be further divided into three sub-categories, planar MOSFETs, lateral double-diffused MOS (LDMOS) devices and vertical double-diffused MOSFETs.

In battery powered electronic devices, a load switch is placed between a power supply and a load. The load switch is configured to connect the load to the power supply or disconnect the load from the power supply. The load switch may be controlled by an external signal. In operation, when the load switch is turned off, the load switch is able to block current from flowing in both directions. On the other hand, when the load switch is turned on, a conductive path is established between the load and the power supply. Through the conductive path, the current flows from the power supply to the load. The load switch may be implemented as an isolation switch having two back-to-back connected transistors. The back-to-back connected transistors are able to achieve bidirectional current blocking. In some applications, one terminal of the load switch is connected to a positive terminal of the power supply (e.g., a battery), and the other terminal of the load switch is connected to a system load. Since both terminals of the load switch are not connected to ground, the load switch is also known as a high side protection apparatus.

In order to prevent electromagnetic Interference (EMI) and/or electrostatic discharge (ESD) from disturbing the operation of the load switch, bidirectional transient voltage suppression (TVS) diodes are included in the load switch. In particular, first bidirectional TVS diodes are placed across the gate and the source of the first transistor of the back-to-back connected transistors. Second bidirectional TVS diodes are placed across the gate and the source of the second transistor of the back-to-back connected transistors. In addition, a first resistor (e.g., a 10 Mega-ohm resistor) is placed in parallel with the first bidirectional TVS diodes. A second resistor (e.g., a 10 Mega-ohm resistor) is placed in parallel with the second bidirectional TVS diodes.

Bidirectional TVS diodes may cause leakage current after a large gate-to-source voltage is applied to the load switch. In a sleep mode or a power shutdown mode, the leakage current can cause significant power losses, thereby reducing the battery life. It would be desirable to have a simple apparatus and method to reduce the leakage current of the load switch so as to extend the battery life. The present disclosure addresses this need.

### SUMMARY

These and other problems are generally solved or circumvented, and technical advantages are generally achieved, by preferred embodiments of the present disclosure which provide a gate drive voltage regulation apparatus for reducing power consumption in a battery powered electronic device.

In accordance with an embodiment, an apparatus comprises a first driver and a second driver configured to drive a first switch and a second switch, respectively, wherein the first switch and the second switch are connected in series, a first voltage regulator and a first charge pump connected in series between a power source and the first driver, wherein the first voltage regulator and the first charge pump are configured such that during a turn-on state of the first switch, a gate-to-source voltage of the first switch is reduced from a normal gate drive voltage potential to a gate drive voltage potential approximately equal to a turn-on threshold of the first switch, and a second voltage regulator and a second charge pump connected in series between the power source and the second driver, wherein the second voltage regulator and the second charge pump are configured such that during a turn-on state of the second switch, a gate-to-source voltage of the second switch is reduced from a normal gate drive voltage potential to a gate drive voltage potential approximately equal to a turn-on threshold of the second switch.

In accordance with another embodiment, a method comprises in a first operating mode of a load switch comprising two back-to-back connected transistors, reducing at least one of a first gate-to-source voltage and a second gate-to-source voltage of the two back-to-back connected transistors from a normal gate drive voltage potential to a reduced gate drive voltage potential, and in a second operating mode of the load switch, increasing the at least one of the first gate-to-source voltage and the second gate-to-source voltage of the two back-to-back connected transistors from the reduced gate drive voltage potential to the normal gate drive voltage potential.

In accordance with yet another embodiment, a controller comprises a first driver configured to drive a first switch of a load switch, a second driver configured to drive a second switch of the load switch, wherein the first switch and the second switch are connected in series, a first voltage regulator and a first charge pump connected in series between a power source and the first driver, a second voltage regulator and a second charge pump connected in series between the power source and the second driver, wherein the first voltage regulator, the first charge pump, the second voltage regulator and the second charge pump are configured such that during a turn-on state of the first switch, a gate-to-source voltage of the first switch is reduced from a normal gate drive voltage potential to a gate drive voltage potential approximately equal to a turn-on threshold of the first switch, and during a turn-on state of the second switch, a gate-to-source voltage of the second switch is reduced from a normal gate drive voltage potential to a gate drive voltage potential approximately equal to a turn-on threshold of the second switch.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 illustrates a block diagram of a gate drive voltage regulation circuit of a load switch in accordance with various embodiments of the present disclosure;

FIG. 2 illustrates another block diagram of the gate drive voltage regulation circuit shown in FIG. 1 in accordance with various embodiments of the present disclosure;

FIG. 3 illustrates an implementation of the gate drive voltage regulation circuit shown in FIG. 1 in accordance with various embodiments of the present disclosure;

FIG. 4 illustrates a schematic diagram of the charge pumps shown in FIG. 1 in accordance with various embodiments of the present disclosure;

FIG. 5 illustrates another implementation of the gate drive voltage regulation circuit in accordance with various embodiments of the present disclosure;

FIG. 6 illustrates a flow chart of operating the gate drive voltage regulation circuit shown in FIG. 1 in accordance with various embodiments of the present disclosure; and

FIG. 7 illustrates a controller for driving the load switch shown in FIG. 1 in accordance with various embodiments of the present disclosure.

Corresponding numerals and symbols in the different figures generally refer to corresponding parts unless otherwise indicated. The figures are drawn to clearly illustrate the relevant aspects of the various embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The present disclosure will be described with respect to preferred embodiments in a specific context, namely a gate drive voltage regulation circuit for reducing power consumption in a battery powered electronic device. The disclosure may also be applied, however, to a variety of electronic devices. Hereinafter, various embodiments will be explained in detail with reference to the accompanying drawings.

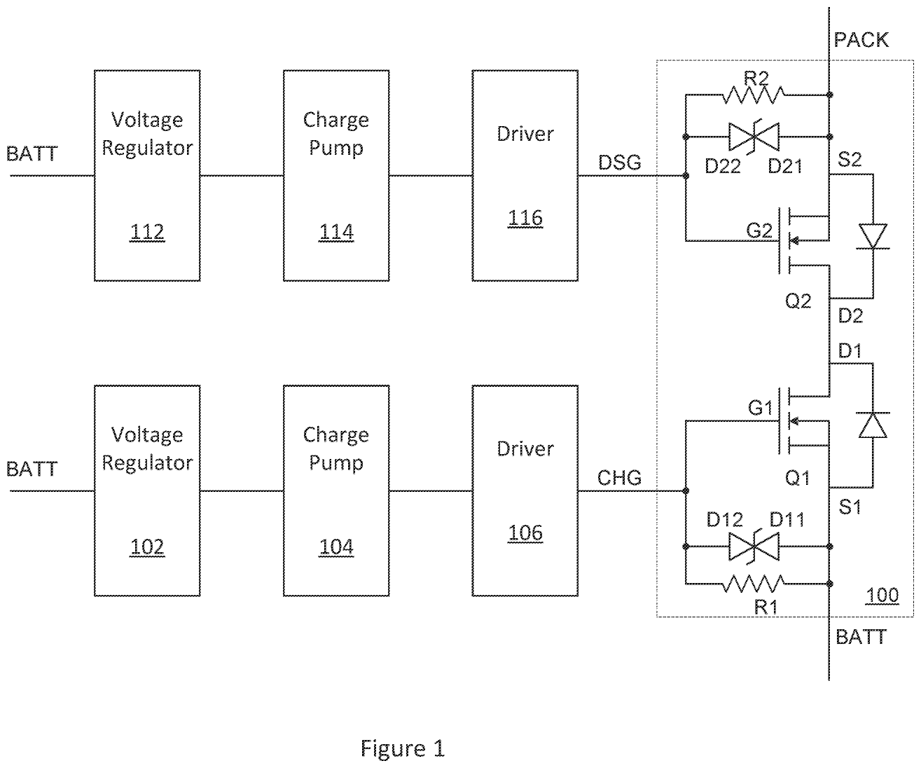

FIG. 1 illustrates a block diagram of a gate drive voltage regulation circuit of a load switch in accordance with various embodiments of the present disclosure. As shown in FIG. 1, the load switch 100 comprises two back-to-back connected N-type transistors Q1 and Q2. A first transistor Q1 comprises a first drain D1, a first gate G1 and a first source S1. A second transistor Q2 comprises a second drain D2, a second gate G2 and a second source S2. The drains of these two N-type transistors are directly connected to each other as shown in FIG. 1. The back-to-back connected N-type transistors shown in FIG. 1 function as a load switch. The load switch is able to achieve bidirectional current blocking. As such, the load switch 100 is also known as an isolation switch.

In accordance with an embodiment, the switches of FIG. 1 (e.g., switches Q1 and Q2) may be metal oxide semiconductor field-effect transistor (MOSFET) devices, super junction transistor (SJT) devices, gallium nitride (GaN) based power devices and/or the like.

The load switch 100 further comprises first bidirectional TVS diodes formed by D11 and D12. The first bidirectional TVS diodes are placed across the gate and the source of Q1. The load switch 100 further comprises second bidirectional TVS diodes formed by D21 and D22. The second bidirectional TVS diodes are placed across the gate and the source of Q2. Furthermore, a first resistor R1 is placed in parallel with the first bidirectional TVS diodes (D11 and D12). In some embodiments, R1 is a 10 Mega-ohm resistor. A second resistor R2 is placed in parallel with the second bidirectional TVS diodes (D21 and D22). In some embodiments, R2 is a 10 Mega-ohm resistor.

During a positive cycle of a voltage transient applied to the gate and source of Q1, the TVS diode D11 is reversed biased while the other diode D12 is forward biased. D11 enters into an avalanche mode to absorb the large current caused by the voltage transient. During the positive cycle of the voltage transient, the voltage across the gate and the source of Q1 is clamped at a voltage level approximately equal to the maximum clamping level provided by D11. Likewise, during a negative cycle of the voltage transient applied to the gate of Q1, the TVS diode D12 is reversed biased while the other diode D11 is forward biased. D12 enters into an avalanche mode to absorb the large current caused by the voltage transient. During the negative cycle of the voltage transient, the voltage across the gate and the source of Q1 is clamped at a voltage level approximately equal to the maximum clamping level provided by D12. The operating principle of D21 and D22 is similar to that of D11 and D12, and hence is not discussed herein to avoid repetition.

The gate drive voltage regulation circuit includes a first voltage regulator 102, a first charge pump 104, a first driver 106, a second voltage regulator 112, a second charge pump 114 and a second driver 116. As shown in FIG. 1, the first voltage regulator 102, the first charge pump 104 and the first driver 106 are connected in cascade between a power source and the gate of Q1. In some embodiments, the power source is the battery coupled to the load switch 100. Throughout the description, the node of the battery is denoted as BATT as shown in FIG. 1. The second voltage regulator 112, the second charge pump 114 and the second driver 116 are connected in cascade between the power source and the gate of Q2.

The first voltage regulator 102 is employed to generate a regulated and adjustable voltage. Such a regulated and adjustable voltage is used to adjust the gate-to-source voltage of Q1. For example, the gate-to-source voltage of Q1 may be adjusted from a normal gate drive voltage (e.g., 8 V) to a reduced gate drive voltage (e.g., a voltage regulated at about 2.5 V or about 4 V). The first charge pump 104 is employed to provide a gate drive voltage higher than the source voltage of Q1 (the BATT node shown in FIG. 1). In some embodiments, the first charge pump 104 has a power conversion ratio of 1:3. The first driver 106 is configured to convert a low power drive signal into a high current drive signal applied to the gate of Q1. Furthermore, the first driver 106 is able to disconnect the first charge pump 104 from the gate of Q1.

The second voltage regulator 112 is employed to generate a regulated and adjustable voltage. Such a regulated and adjustable voltage is used to adjust the gate-to-source voltage of Q2. For example, the gate-to-source voltage of Q2 may be adjusted from a normal gate drive voltage (e.g., 8 V) to a reduced gate drive voltage (e.g., a voltage regulated at about 2.5 V or about 4 V). The second charge pump 114 is employed to provide a gate drive voltage higher than the source voltage of Q2 (the PACK node shown in FIG. 1). In some embodiments, the second charge pump 114 has a power conversion ratio of 1:3. The second driver 116 is configured to convert a low power drive signal into a high current drive signal applied to the gate of Q2. Furthermore, the second driver 116 is able to disconnect the second charge pump 114 from the gate of Q2.

In operation, the first voltage regulator 102 and the first charge pump 104 are configured such that a gate-to-source voltage of the first switch Q1 is reduced from a normal gate drive voltage potential to a gate drive voltage potential approximately equal to a turn-on threshold of the first switch Q1. For example, under a light load operating condition, the gate-to-source voltage of the first switch Q1 may be lowered from a normal gate drive voltage potential (e.g., 8 V) to a reduced gate drive voltage potential (e.g., a voltage regulated at about 2.5 V or about 4 V) for reducing the leakage current flowing through the first TVS diodes (D11 and D12).

In order to further reduce the average current flowing through the first driver 106, the gate-to-source voltage of Q1 is configured to fluctuate around the regulation point (e.g., a voltage regulated at about 2.5 V or about 4 V) through periodically turning on and turning off the first charge pump 104. In operation, the first charge pump 104 is temporarily disabled so as to reduce the average current flowing through the first driver 106. Once the first gate-to-source voltage of Q1 drops below a first predetermined threshold, the first charge pump 104 is enabled again. After the first charge pump 104 has been enabled, predetermined hysteresis is added on top of the first predetermined threshold so that the first gate-to-source voltage is charged to a voltage level exceeding the first predetermined threshold.

In operation, the second voltage regulator 112 and the second charge pump 114 are configured such that a gate-to-source voltage of the second switch Q2 is reduced from a normal gate drive voltage potential to a gate drive voltage potential approximately equal to a turn-on threshold of the second switch Q2. For example, under a light load operating condition, the gate-to-source voltage of the second switch Q2 may be lowered from a normal gate drive voltage potential (e.g., 8 V) to a reduced gate drive voltage potential (e.g., a voltage regulated at about 2.5 V or about 4 V) for reducing the leakage current flowing through the second TVS diodes (D21 and D22).

In order to further reduce the average current flowing through the second driver 116, the gate-to-source voltage of Q2 is configured to fluctuate around the regulation point (e.g., a voltage regulated at about 2.5 V or about 4 V) through periodically turning on and turning off the second charge pump 114. In operation, the second charge pump 114 is temporarily disabled so as to reduce the average current flowing through the second driver 116. Once the gate-to-source voltage of the second switch Q2 drops below a second predetermined threshold, the second charge pump 114 is enabled again. After the second charge pump 114 has been enabled, predetermined hysteresis is added on top of the second predetermined threshold so that the gate-to-source voltage of the second switch Q2 is charged to a voltage level exceeding the second predetermined threshold.

It should be noted that the first switch Q1 and the second switch Q2 form the load switch 100. A current may flow from the battery to the load through the load switch. In some embodiment, under a light load operating condition, both the gate-to-source voltage of the first switch Q1 and the gate-to-source voltage of the second switch Q2 are reduced simultaneously to reduce the leakage current of the load switch. In alternative embodiments, the gate-to-source voltage of the first switch Q1 and the gate-to-source voltage of the second switch Q2 are reduced in an alternating manner. Furthermore, at least one of the gate-to-source voltages of Q1 and Q2 is reduced to improve the power consumption of the load switch 100.

One advantageous feature of having the gate drive voltage regulation circuit shown in FIG. 1 is the gate-to-source leakage currents of Q1 and Q2 can be significantly reduced through lowering the gate-to-source voltage of the first switch Q1 and the gate-to-source voltage of the second switch Q2. In some embodiments, the total leakage current can be reduced from 34.4 microamperes to 2.4 microamperes.

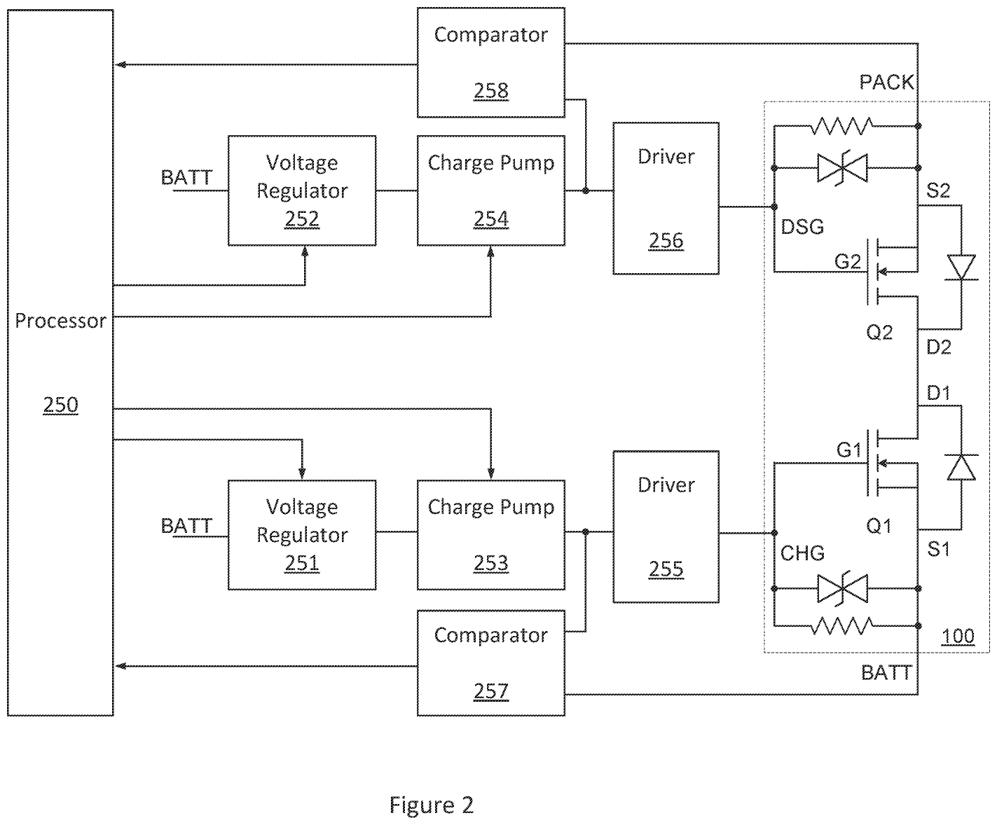

FIG. 2 illustrates another block diagram of the gate drive voltage regulation circuit shown in FIG. 1 in accordance with various embodiments of the present disclosure. The block diagram shown in FIG. 2 is similar to that shown in FIG. 1 except that a first comparator 257, a second comparator 258 and a processor 250 have been added.

As shown in FIG. 2, the first comparator 257 has a first input connected to the input of the first driver 255, a second input connected to the BATT node (the source of Q1), and an output connected to the processor 250. The first comparator 257 is employed to detect the gate-to-source voltage of the first switch Q1, compare the detected voltage with a predetermined reference, and feed the comparison result to the processor 250.

It should be noted that when the first switch Q1 is turned on, the voltage on the input of the first driver 255 is approximately equal to the voltage on the gate of the first switch Q1. As such, the gate-to-source voltage of the first switch Q1 can be obtained by connecting the first input of the first comparator 257 to the input of the first driver 255.

The second comparator 258 has a first input connected to the input of the second driver 256, a second input connected to the PACK node (the source of Q2), and an output connected to the processor 250. The second comparator 258 is employed to detect the gate-to-source voltage of the second switch Q2, compare the detected voltage with a predetermined reference, and feed the comparison result to the processor 250.

The processor 250 is able to generate control signals for the first voltage regulator 251, the first charge pump 253, the second voltage regulator 252 and the second charge pump 254. In particular, the processor 250 is configured to detect a plurality of operating parameters of the load switch, and determine whether the load switch enters into a power saving operating mode (e.g., a light load operating mode) based on the plurality of operating parameters. Upon determining that the load switch has entered into a power saving operating mode, the processor 250 configures the first voltage regulator 251 and/or the second voltage regulator 252 to lower the output voltages so that the gate-to-source voltages of Q1 and Q2 are approximately equal to a turn-on threshold of Q1 and Q2. Furthermore, the processor 250 is able to temporarily disable the first charge pump 253 and/or the second charge pump 254 so as to reduce the average currents flowing through the respective drivers.

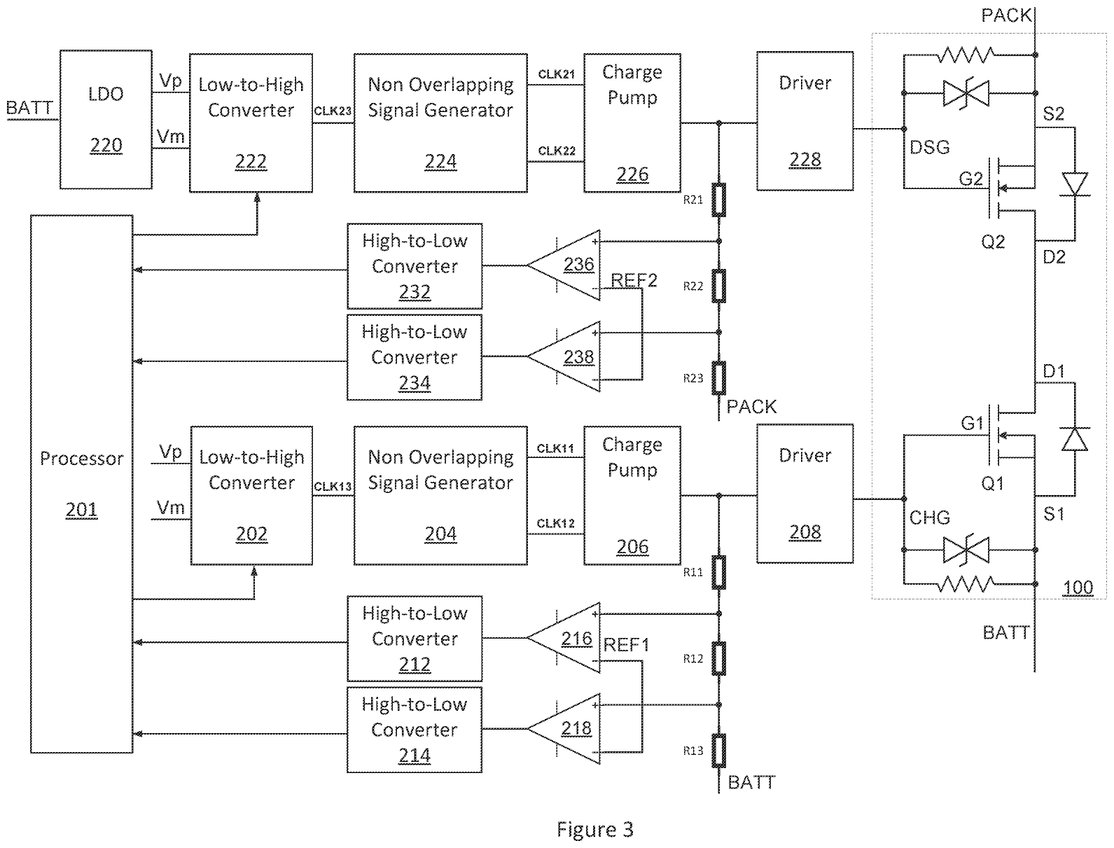

FIG. 3 illustrates an implementation of the gate drive voltage regulation circuit shown in FIG. 1 in accordance with various embodiments of the present disclosure. As shown in FIG. 3, a voltage regulator such as a low-dropout regulator (LDO) 220 is employed to generate two rail voltages Vp and Vm. The rail voltages Vp and Vm are applied to the gate of Q1 through the first charge pump 206. In some embodiments, the first charge pump 206 is a charge pump having a conversion ratio of 1:3. In other words, the voltage across the gate and the source of Q1 is approximately equal to three times the difference of Vp and Vm (3×(Vp−Vm)). Likewise, the rail voltages Vp and Vm are applied to the gate of Q2 through the second charge pump 226. In some embodiments, the second charge pump 226 is a charge pump having a conversion ratio of 1:3. In other words, the voltage across the gate and the source of Q2 is approximately equal to three times the difference of Vp and Vm (3×(Vp−Vm)).

A first low-to-high converter 202, a first non-overlapping signal generator 204, a first charge pump 206 and a first driver 208 are coupled between Vp, Vm, and the gate of Q1. A first divider formed by R11, R12 and R13 is connected between the input of the first driver 208 and the BATT node.

A first comparator 216 has a non-inverting input connected to a common node of R11 and R12, an inverting input connected to a first predetermined reference REF1, and an output fed into an input of a first high-to-low converter 212. A second comparator 218 has a non-inverting input connected to a common node of R12 and R13, an inverting input connected to the first predetermined reference REF1, and an output fed into an input of a second high-to-low converter 214. The first comparator 216 and the second comparator 218 are configured to detect the gate-to-source voltage of Q1. The first high-to-low converter 212 is employed to translate a control signal in a high voltage domain to a control signal in a low voltage domain. The control signal in the low voltage domain can be processed by the processor 201 directly. Likewise, the second high-to-low converter 214 is employed to translate a control signal in a high voltage domain to a control signal in a low voltage domain. The output signal of the second high-to-low converter 214 can be processed by the processor 201 directly.

Based on the control signals generated by the first high-to-low converter 212 and the second high-to-low converter 214, the processor 201 is able to control the operation of the first charge pump 206. In particular, the processor 201 may temporarily disable the first charge pump 206 so as to reduce the average currents flowing through the first driver 208. Furthermore, the processor 201 may enable the first charge pump 206 after the gate-to-source voltage of Q1 drops below a first predetermined threshold. After the first charge pump 206 has been enabled, hysteresis is added on top of the first predetermined threshold so that the gate-to-source voltage of Q1 is charged to a voltage level exceeding the first predetermined threshold. It should be noted the hysteresis is added through the first comparator 216 and the second comparator 218.

A second low-to-high converter 222, a second non-overlapping signal generator 224, a second charge pump 226 and a second driver 228 are coupled between Vp, Vm, and the gate of Q2. A second divider formed by R21, R22 and R23 is connected between the input of the second driver 228 and the PACK node.

A third comparator 236 has a non-inverting input connected to a common node of R21 and R22, an inverting input connected to a second predetermined reference REF2, and an output fed into an input of a third high-to-low converter 232. A fourth comparator 238 has a non-inverting input connected to a common node of R22 and R23, an inverting input connected to the second predetermined reference REF2, and an output fed into an input of a fourth high-to-low converter 234. The third comparator 236 and the fourth comparator 238 are configured to detect the gate-to-source voltage of Q2. The third high-to-low converter 232 is employed to translate a control signal in a high voltage domain to a control signal in a low voltage domain. The control signal in the low voltage domain can be processed by the processor 201 directly. Likewise, the fourth high-to-low converter 234 is employed to translate a control signal in a high voltage domain to a control signal in a low voltage domain. The output signal of the fourth high-to-low converter 234 can be processed by the processor 201 directly.

Based on the control signals generated by the third high-to-low converter 232 and the fourth high-to-low converter 234, the processor 201 is able to control the operation of the second charge pump 226. In particular, the processor 201 may temporarily disable the second charge pump 226 so as to reduce the average currents flowing through the second driver 228. Furthermore, the processor 201 may enable the second charge pump 226 after the gate-to-source voltage of Q2 drops below a second predetermined threshold. After the second charge pump 226 has been enabled, hysteresis is added on top of the second predetermined threshold so that the gate-to-source voltage of Q2 is charged to a voltage level exceeding the second predetermined threshold. It should be noted the hysteresis is added through the third comparator 236 and the fourth comparator 238.

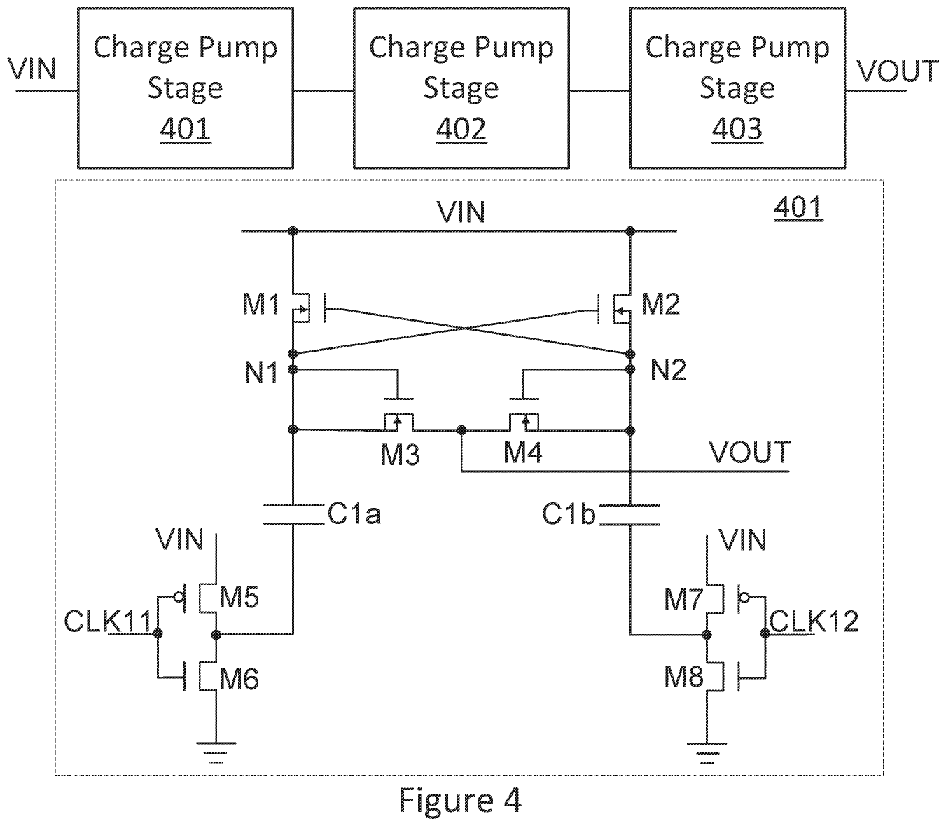

FIG. 4 illustrates a schematic diagram of the charge pumps shown in FIG. 1 in accordance with various embodiments of the present disclosure. Referring back to FIG. 1, the first charge pump 104 and the second charge pump 114 have the same structure. As shown in FIG. 4, the charge pump (e.g., first charge pump 104 shown in FIG. 1) comprises three stages 401, 402 and 403 connected in cascade between an input terminal and an output terminal. These three stages have the same structure. For simplicity, only the first stage 401 is discussed in detail below.

As shown in FIG. 4, a first transistor M1 is connected between VIN and a node N1. A second transistor M2 is connected between VIN and a node N2. A gate of M1 is connected to the node N2. A gate of M2 is connected to the node N1. Transistors M3 and M4 are connected in series between nodes N1 and N2. The gate of M3 is connected to the node N1. The gate of M4 is connected to the node N2. The output terminal of the first stage 401 is connected to the common node of M3 and M4.

Transistors M5 and M6 are connected in series between VIN and ground. The gates of M5 and M6 are connected together and configured to receive a first clock signal CLK11. Transistors M7 and M8 are connected in series between VIN and ground. The gates of M7 and M8 are connected together and configured to receive a first clock signal CLK12. In some embodiments, CLK11 and CLK12 are two complementary signals.

A first capacitor C1a is connected between N1 and a common node of M5 and M6. A second capacitor C1b is connected between N2 and a common node of M7 and M8.

The three stages 401, 402 and 403 of the charge pump are able to achieve a conversion ratio of 1:3. The operation principle of the charge pump having a conversion ratio of 1:3 is well known, and hence is not discussed herein.

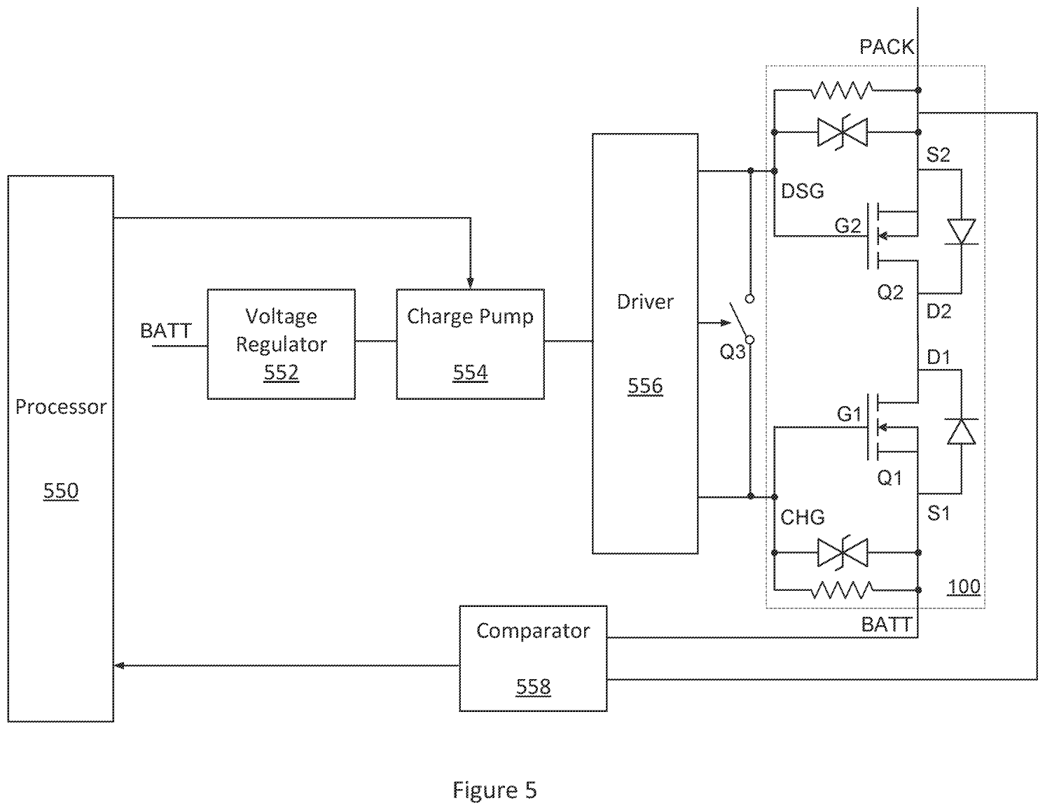

FIG. 5 illustrates another implementation of the gate drive voltage regulation circuit in accordance with various embodiments of the present disclosure. As shown in FIG. 5, a switch Q3 is connected between the gate of Q1 and the gate of Q2. A voltage regulator 552, a charge pump 554 and a driver 556 are connected between a power source (e.g., the BATT node) and the gates of Q1 and Q2. A comparator 558 has a first input connected to the PACK node, a second input connected to the BATT node, and an output fed into an input of a processor 550.

In operation, during the turn-on state of the load switch 100, the switch Q3 is turned on. The comparator 558 detects a voltage across the source of the first switch Q1 and the source of the second switch Q2. Based on the detected voltage (the voltage across the source of the first switch Q1 and the source of the second switch Q2), the processor 550 is configured to regulate a gate-to-source voltage of the load switch 100 to a voltage level approximately equal to a turn-on threshold of the load switch 100. Furthermore, the processor 550 is configured to temporarily disable the charge pump 554 to reduce the average current flowing through the driver 556. The processor 550 is configured to enable the charge pump 554 once the voltage across the source of the first switch Q1 and the source of the second switch Q2 exceeds a predetermined threshold.

In alternative embodiments, the processor 550 is configured to enable the charge pump 554 for a predetermined time. After the predetermined time ends, the charge pump 554 is temporarily disabled again.

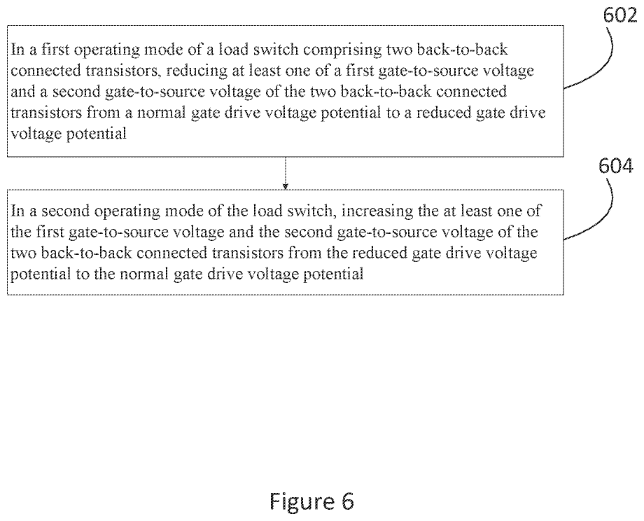

FIG. 6 illustrates a flow chart of operating the gate drive voltage regulation circuit shown in FIG. 1 in accordance with various embodiments of the present disclosure. This flowchart shown in FIG. 6 is merely an example, which should not unduly limit the scope of the claims. One of ordinary skill in the art would recognize many variations, alternatives, and modifications. For example, various steps illustrated in FIG. 6 may be added, removed, replaced, rearranged and repeated.

Referring back to FIG. 1, a first driver is configured to drive a first switch of a load switch. A second driver is configured to drive a second switch of the load switch. The first switch and the second switch are connected in series. A first voltage regulator and a first charge pump connected in series between a power source and the first driver. A second voltage regulator and a second charge pump connected in series between the power source and the second driver. A processor is configured to control the first voltage regulator, the first charge pump, the second voltage regulator and the second charge pump to reduce the leakage current of the load switch.

At step 602, in a first operating mode of the load switch comprising two back-to-back connected transistors, at least one of a first gate-to-source voltage and a second gate-to-source voltage of the two back-to-back connected transistors is reduced from a normal gate drive voltage potential to a reduced gate drive voltage potential.

In some embodiments, the first operating mode is a mode in which a reduced gate-to-source voltage and an increased on resistance are acceptable for the host system of the load switch. For example, the first operating mode may occur at a light load operating condition of the host system (e.g., a sleep mode or a power shutdown mode of a battery powered electronic device).

At step 604, in a second operating mode of the load switch, the at least one of the first gate-to-source voltage and the second gate-to-source voltage of the two back-to-back connected transistors is increased from the reduced gate drive voltage potential to the normal gate drive voltage potential.

In some embodiments, the second operating mode is a mode in which a reduced gate-to-source voltage and an increased on resistance are not acceptable for the host system of the load switch. For example, the second operating mode may occur at a heavy load operating condition of the host system.

The method further comprises detecting a plurality of operating parameters of the load switch, and determining whether the load switch enters into the first operating mode based on the plurality of operating parameters.

The load switch comprises a first switch and a second switch connected in series, and wherein a drain of the first switch is connected to a drain of the second switch, a source of the first switch is configured to be coupled to a load, and a source of the second switch is configured to be coupled to a battery.

The method further comprises coupling a first voltage regulator, a first charge pump and a first driver between a power source and a gate of the first switch, and coupling a second voltage regulator, a second charge pump and a second driver between the power source and a gate of the second switch.

The first charge pump and the second charge pump have a power conversion ratio of 1:3.

The method further comprises in the first operating mode of a load switch, temporarily disabling the first charge pump so as to reduce an average current flowing through the first driver, and enabling the first charge pump once the first gate-to-source voltage drops below a first predetermined threshold, wherein after the first charge pump has been enabled, hysteresis is added on top of the first predetermined threshold so that the first gate-to-source voltage is charged to a voltage level exceeding the first predetermined threshold.

The method further comprises adjusting an output voltage of the first voltage regulator to reduce the first gate-to-source voltage of the two back-to-back connected transistors from the normal gate drive voltage potential to the reduced gate drive voltage potential, and adjusting an output voltage of the second voltage regulator to reduce the second gate-to-source voltage of the two back-to-back connected transistors from the normal gate drive voltage potential to the reduced gate drive voltage potential.

The method further comprises turning on a switch coupled between the gate of the first switch and the gate of the second switch; detecting a voltage across the source of the first switch and the source of the second switch, and regulating a gate-to-source voltage of the load switch to a voltage level approximately equal to a turn-on threshold of the load switch based on the voltage across the source of the first switch and the source of the second switch.

The method further comprises temporarily disabling a charge pump configured to provide power for charging the gate-to-source voltage; and enabling the charge pump once the voltage across the source of the first switch and the source of the second switch exceeds a predetermined threshold, wherein after the charge pump has been enabled, hysteresis is added so that the voltage across the source of the first switch and the source of the second switch drops below the predetermined threshold minus the hysteresis.

The method further comprises temporarily disabling a charge pump configured to provide power for charging the gate-to-source voltage; and enabling the charge pump once the voltage across the source of the first switch and the source of the second switch exceeds a predetermined threshold, wherein after the charge pump is enabled for a predetermined time, the charge pump is temporarily disabled again.

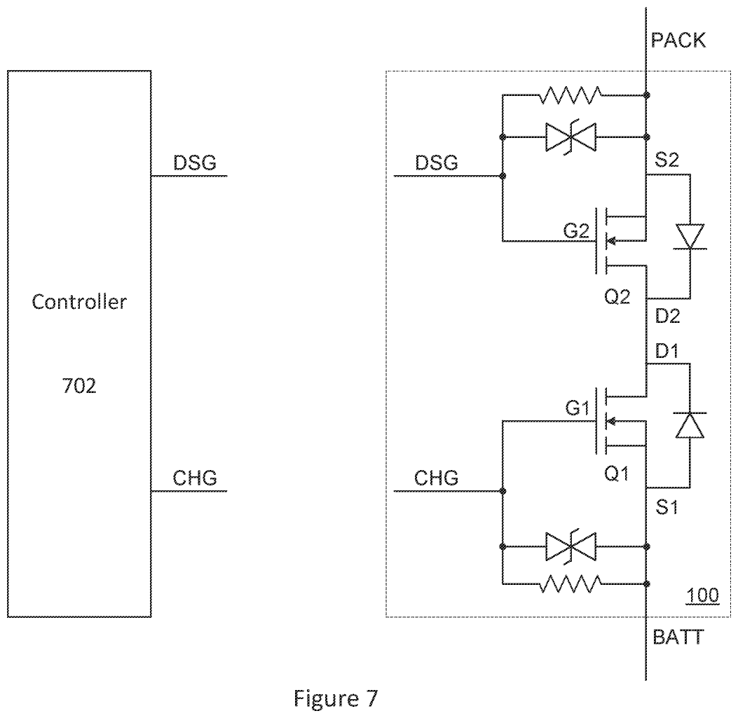

FIG. 7 illustrates a controller for driving the load switch shown in FIG. 1 in accordance with various embodiments of the present disclosure. The controller 702 comprises a first driver, a second a driver and other function units. The first driver is configured to generate a first gate drive signal applied to the first gate CHG of a first switch Q1. The second driver is configured to generate a second gate drive signal applied to the second gate DSG of the second switch.

It should be noted that the controller 702 having two drivers described above is merely an example, which should not unduly limit the scope of the claims. One of ordinary skill in the art would recognize many variations, alternatives, and modifications.

Although embodiments of the present disclosure and its advantages have been described in detail, it should be understood that various changes, substitutions and alterations can be made herein without departing from the spirit and scope of the disclosure as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. An apparatus comprising:
a first driver and a second driver configured to drive a first switch and a second switch, respectively, wherein the first switch and the second switch are connected in series;
a first voltage regulator and a first charge pump connected in series between a power source and the first driver, wherein the first voltage regulator and the first charge pump are configured such that during a turn-on state of the first switch, a gate-to-source voltage of the first switch is reduced from a normal gate drive voltage potential to a gate drive voltage potential approximately equal to a turn-on threshold of the first switch; and
a second voltage regulator and a second charge pump connected in series between the power source and the second driver, wherein the second voltage regulator and the second charge pump are configured such that during a turn-on state of the second switch, a gate-to-source voltage of the second switch is reduced from a normal gate drive voltage potential to a gate drive voltage potential approximately equal to a turn-on threshold of the second switch.

2. The apparatus of claim 1, wherein:
the first switch is a first N-type MOSFET, and the second switch is a second N-type MOSFET, and wherein the first switch and the second switch form a load switch configured to be coupled between a battery and a load.

3. The apparatus of claim 1, wherein:
a drain of the first switch is connected to a drain of the second switch;
a source of the first switch is configured to be coupled to a load; and
a source of the second switch is configured to be coupled to a battery.

4. The apparatus of claim 1, wherein:
the first charge pump is temporarily disabled to reduce an average current flowing through the first driver; and
the first charge pump is enabled once the first gate-to-source voltage drops below a first predetermined threshold.

5. The apparatus of claim 1, wherein:
the second charge pump is temporarily disabled to reduce an average current flowing through the second driver; and
the second charge pump is enabled once the second gate-to-source voltage drops below a second predetermined threshold.

6. The apparatus of claim 5, wherein:
the first charge pump has a power conversion ratio of 1:3; and
the second charge pump has a power conversion ratio of 1:3.

7. The apparatus of claim 1, wherein:
first TVS diodes are connected between a gate and a source of the first switch;
a first resistor is connected in parallel with the first TVS diodes;
second TVS diodes are connected between a gate and a source of the second switch; and
a second resistor is connected in parallel with the second TVS diodes.

8. A method comprising:
in a first operating mode of a load switch comprising two back-to-back connected transistors, reducing at least one of a first gate-to-source voltage and a second gate-to-source voltage of the two back-to-back connected transistors from a normal gate drive voltage potential to a reduced gate drive voltage potential; and
in a second operating mode of the load switch, increasing the at least one of the first gate-to-source voltage and the second gate-to-source voltage of the two back-to-back connected transistors from the reduced gate drive voltage potential to the normal gate drive voltage potential.

9. The method of claim 8, further comprising:
detecting a plurality of operating parameters of the load switch; and
determining whether the load switch enters into the first operating mode based on the plurality of operating parameters.

10. The method of claim 8, wherein:
the load switch comprises a first switch and a second switch connected in series, and wherein:
a drain of the first switch is connected to a drain of the second switch;
a source of the first switch is configured to be coupled to a load; and
a source of the second switch is configured to be coupled to a battery.

11. The method of claim 10, further comprising:
coupling a first voltage regulator, a first charge pump and a first driver between a power source and a gate of the first switch; and
coupling a second voltage regulator, a second charge pump and a second driver between the power source and a gate of the second switch.

12. The method of claim 11, wherein:
the first charge pump and the second charge pump have a power conversion ratio of 1:3.

13. The method of claim 11, further comprising:
in the first operating mode of the load switch, temporarily disabling the first charge pump so as to reduce an average current flowing through the first driver; and
enabling the first charge pump once the first gate-to-source voltage drops below a first predetermined threshold, wherein after the first charge pump has been enabled, hysteresis is added on top of the first predetermined threshold so that the first gate-to-source voltage is charged to a voltage level exceeding the first predetermined threshold.

14. The method of claim 11, further comprising:
adjusting an output voltage of the first voltage regulator to reduce the first gate-to-source voltage of the two back-to-back connected transistors from the normal gate drive voltage potential to the reduced gate drive voltage potential; and
adjusting an output voltage of the second voltage regulator to reduce the second gate-to-source voltage of the two back-to-back connected transistors from the normal gate drive voltage potential to the reduced gate drive voltage potential.

15. The method of claim 11, further comprising:
turning on a switch coupled between the gate of the first switch and the gate of the second switch;
detecting a voltage across the source of the first switch and the source of the second switch; and
regulating a gate-to-source voltage of the load switch to a voltage level approximately equal to a turn-on threshold of the load switch based on the voltage across the source of the first switch and the source of the second switch.

16. The method of claim 15, further comprising:
temporarily disabling a charge pump configured to provide power for charging the gate-to-source voltage of the load switch; and
enabling the charge pump once the voltage across the source of the first switch and the source of the second switch exceeds a predetermined threshold, wherein after the charge pump has been enabled, hysteresis is added so that the voltage across the source of the first switch and the source of the second switch is able to drop below the predetermined threshold minus the hysteresis.

17. The method of claim 15, further comprising:
temporarily disabling a charge pump configured to provide power for charging the gate-to-source voltage; and
enabling the charge pump once the voltage across the source of the first switch and the source of the second switch exceeds a predetermined threshold, wherein after the charge pump is enabled for a predetermined time, the charge pump is temporarily disabled again.

18. A controller comprising:
a first driver configured to drive a first switch of a load switch;
a second driver configured to drive a second switch of the load switch, wherein the first switch and the second switch are connected in series;
a first voltage regulator and a first charge pump connected in series between a power source and the first driver;
a second voltage regulator and a second charge pump connected in series between the power source and the second driver, wherein the first voltage regulator, the first charge pump, the second voltage regulator and the second charge pump are configured such that:
during a turn-on state of the first switch, a gate-to-source voltage of the first switch is reduced from a normal gate drive voltage potential to a gate drive voltage potential approximately equal to a turn-on threshold of the first switch; and
during a turn-on state of the second switch, a gate-to-source voltage of the second switch is reduced from a normal gate drive voltage potential to a gate drive voltage potential approximately equal to a turn-on threshold of the second switch.

19. The controller of claim 18, wherein:
the power source is a battery;
the first switch is a first N-type MOSFET; and
the second switch is a second N-type MOSFET, and wherein:
a drain of the first switch is connected to a drain of the second switch;
a source of the first switch is configured to be coupled to a load; and
a source of the second switch is configured to be coupled to the battery.

20. The controller of claim 18, wherein:
during the turn-on state of the first switch, the first charge pump is temporarily disabled to reduce an average current flowing through the first driver; and
during the turn-on state of the second switch, the second charge pump is temporarily disabled to reduce an average current flowing through the second driver.
